(19) United States
(12) Patent Application Publication
(10) Pub. No.: US 2023/0039661 A1
(43) Pub. Date: Feb. 9, 2023

(54) INTERCONNECT STRUCTURE AND METHODS OF FORMING THE SAME

(71) Applicant: TAIWAN SEMICONDUCTOR MANUFACTURING COMPANY, LTD., Hsinchu (TW)

(72) Inventors: Hwei-Jay CHU, Hsinchu (TW); Chieh-Han WU, Kaohsiung (TW); Hsin-Chieh YAO, Hsinchu (TW); Wei-Hao LIAO, Taichung (TW); Yu-Teng DAI, Hsinchu (TW); Hsi-Wen TIEN, Hsinchu (TW); Chih Wei LU, Hsinchu (TW)

(21) Appl. No.: 17/695,438

(22) Filed: Mar. 15, 2022

Related U.S. Application Data
(60) Provisional application No. 63/230,147, filed on Aug. 6, 2021.

(51) Int. Cl. H01L 23/522; H01L 21/768; H01L 23/528

(52) U.S. Cl. CPC H01L 23/5226; H01L 21/76877; H01L 21/76831; H01L 23/528

(57) ABSTRACT

An interconnect structure and methods of forming the same are described. In some embodiments, the structure includes a dielectric layer, a first conductive feature disposed in the dielectric layer, and a second conductive feature disposed over the first conductive feature. The second conductive feature includes a first sidewall, a first bottom, and a first angle between the first sidewall and the first bottom. The structure further includes a third conductive feature disposed over the dielectric layer and adjacent the second conductive feature. The third conductive feature includes a second sidewall, a second bottom, and a second angle between the second sidewall and the second bottom, the second angle is substantially different from the first angle, and the second and third conductive features are partially overlapping in an axis substantially parallel to a major surface of the substrate.

### BACKGROUND

As the semiconductor industry introduces new generations of integrated circuits (IC) having higher performance and more functionality, the density of the elements forming the ICs increases, while the dimensions, sizes and spacing between components or elements are reduced. In the past, such reductions were limited only by the ability to define the structures photo-lithographically, device geometries having smaller dimensions created new limiting factors. For example, as the distance between adjacent conductive features in the dielectric material in the back-end-of-line (BEOL) interconnect structure gets smaller, parasitic capacitance effect increases. Therefore, improved interconnect structures are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of one of various stages of manufacturing a semiconductor device structure, in accordance with some embodiments.

FIG. 1B is a cross-sectional side view of the stage of manufacturing the semiconductor device structure taken along line A-A of FIG. 1A, in accordance with some embodiments.

FIG. 2 is a cross-sectional side view of a stage of manufacturing the semiconductor device structure, in accordance with some embodiments.

FIGS. 3A-3D are cross-sectional side views of various stages of manufacturing an interconnect structure, in accordance with some embodiments.

FIGS. 4-11 are cross-sectional side views of various stages of manufacturing the interconnect structure, in accordance with some embodiments.

FIG. 12 is a top view of the interconnect structure shown in FIG. 11, in accordance with some embodiments.

FIG. 13 is a cross-sectional side view of one of various stages of manufacturing the interconnect structure, in accordance with some embodiments.

FIGS. 14 and 15 are cross-sectional side views of various stages of manufacturing the interconnect structure, in accordance with alternative embodiments.

FIG. 16 is a top view of the interconnect structure shown in FIG. 15, in accordance with alternative embodiments.

FIG. 17 is a cross-sectional side view of one of various stages of manufacturing the interconnect structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

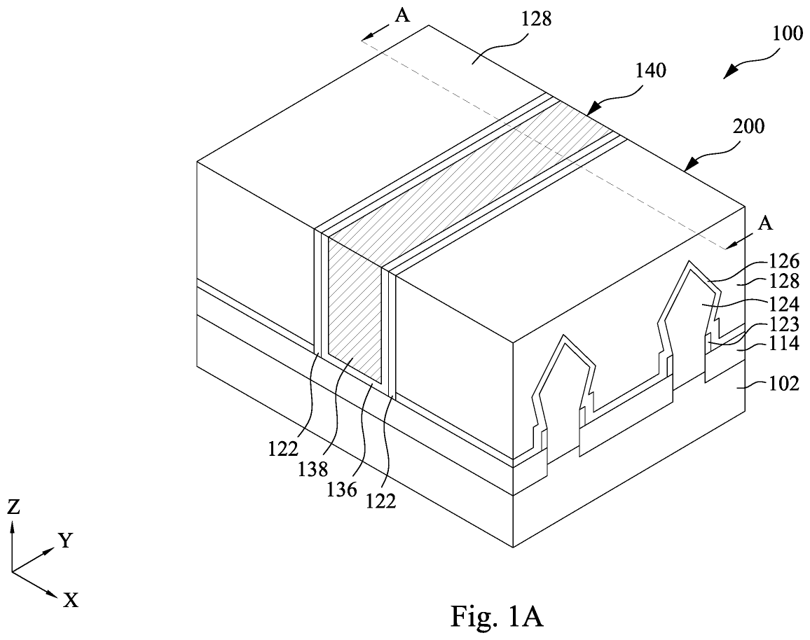

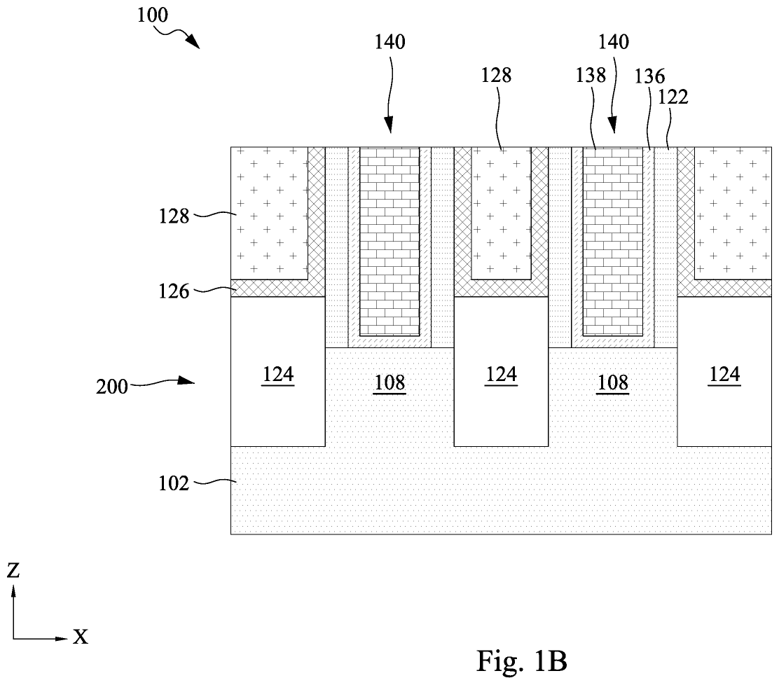

FIGS. 1A and 1B illustrate a stage of manufacturing a semiconductor device structure 100. As shown in FIGS. 1A and 1B, the semiconductor device structure 100 includes a substrate 102 and one or more devices 200 formed on the substrate 102. The substrate 102 may be a semiconductor substrate. In some embodiments, the substrate 102 includes a single crystalline semiconductor layer on at least the surface of the substrate 102. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of Si. In some embodiments, the substrate 102 is a silicon-on-insulator (SOI) substrate, which includes an insulating layer (not shown) disposed between two silicon layers. In one aspect, the insulating layer is an oxygen-containing material, such as an oxide.

The substrate 102 may include one or more buffer layers (not shown) on the surface of the substrate 102. The buffer layers can serve to gradually change the lattice constant from that of the substrate to that of the source/drain regions. The buffer layers may be formed from epitaxially grown crystalline semiconductor materials such as, but not limited to Si, Ge, germanium tin (GeSn), SiGe, GaAs, InSb, GaP, GaSb, InAlAs, InGaAs, GaSbP, GaAsSb, GaN, GaP, and InP.

The substrate 102 may include various regions that have been suitably doped with impurities (e.g., p-type or n-type impurities). The dopants are, for example phosphorus for an n-type fin field effect transistor (FinFET) and boron for a p-type FinFET.

As described above, the devices 200 may be any suitable devices, such as transistors, diodes, imaging sensors, resistors, capacitors, inductors, memory cells, or a combination thereof. In some embodiments, the devices 200 are transistors, such as planar field effect transistors (FETs), FinFETs, nanostructure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels. An example of the device 200 formed on the substrate 102 is a FinFET, which is shown in FIGS. 1A and 1B. The device 200 includes source/drain (S/D) regions 124 and gate stacks 140 (only one is shown in FIG. 1A). Each gate stack 140 may be disposed between S/D regions 124 serving as source regions and S/D regions 124 serving as drain regions. For example, each gate stack 140 may extend along the Y-axis between one or more S/D regions 124 serving as source regions and one or more S/D regions 124 serving as drain regions. As shown in FIG. 1B, two gate stacks 140 are formed on the substrate 102. In some embodiments, more than two gate stacks 140 are formed on the substrate 102. Channel regions 108 are formed between S/D regions 124 serving as source regions and S/D regions 124 serving as drain regions.

The S/D regions 124 may include a semiconductor material, such as Si or Ge, a III-V compound semiconductor, a II-VI compound semiconductor, or other suitable semiconductor material. Exemplary S/D region 124 may include, but are not limited to, Ge, SiGe, GaAs, AlGaAs, GaAsP, SiP, InAs, AlAs, InP, GaN, InGaAs, InAlAs, GaSb, AlP, GaP, and the like. The S/D regions 124 may include p-type dopants, such as boron; n-type dopants, such as phosphorus or arsenic; and/or other suitable dopants including combinations thereof. The S/D regions 124 may be formed by an epitaxial growth method using CVD, atomic layer deposition (ALD) or molecular beam epitaxy (MBE). The channel regions 108 may include one or more semiconductor materials, such as Si, Ge, GeSn, SiGe, GaAs, InSb, GaP, GaSb, InAlAs, InGaAs, GaSbP, GaAsSb, GaN, GaP, or InP. In some embodiments, the channel regions 108 include the same semiconductor material as the substrate 102. In some embodiments, the devices 200 are FinFETs, and the channel regions 108 are a plurality of fins disposed below the gate stacks 140. In some embodiments, the devices 200 are nanostructure transistors, and the channel regions 108 are surrounded by the gate stacks 140.

As shown in FIGS. 1A and 1B, each gate stack 140 includes a gate electrode layer 138 disposed over the channel region 108 (or surrounding the channel region 108 for nanostructure transistors). The gate electrode layer 138 may be a metal-containing material such as tungsten, cobalt, aluminum, ruthenium, copper, multilayers thereof, or the like, and can be deposited by ALD, plasma enhanced chemical vapor deposition (PECVD), MBD, physical vapor deposition (PVD), or any suitable deposition technique. Each gate stack 140 may further include a gate dielectric layer 136 disposed over the channel region 108. The gate electrode layer 138 may be disposed over the gate dielectric layer 136. In some embodiments, an interfacial layer (not shown) may be disposed between the channel region 108 and the gate dielectric layer 136, and one or more work function layers (not shown) may be formed between the gate dielectric layer 136 and the gate electrode layer 138. The interfacial dielectric layer may include a dielectric material, such as an oxygen-containing material or a nitrogen-containing material, or multilayers thereof, and may be formed by any suitable deposition method, such as CVD, PECVD, or ALD. The gate dielectric layer 136 may include a dielectric material such as an oxygen-containing material or a nitrogen-containing material, a high-k dielectric material having a k value greater than that of silicon dioxide, or multilayers thereof. The gate dielectric layer 136 may be formed by any suitable method, such as CVD, PECVD, or ALD. In some embodiments, the gate dielectric layer 136 may be a conformal layer. The term “conformal” may be used herein for ease of description upon a layer having substantial same thickness over various regions. The one or more work function layers may include aluminum titanium carbide, aluminum titanium oxide, aluminum titanium nitride, or the like.

Gate spacers 122 are formed along sidewalls of the gate stacks 140 (e.g., sidewalls of the gate dielectric layers 136). The gate spacers 122 may include silicon oxycarbide, silicon nitride, silicon oxynitride, silicon carbon nitride, the like, multi-layers thereof, or a combination thereof, and may be deposited by CVD, ALD, or other suitable deposition technique.

As shown in FIG. 1A, fin sidewall spacers 123 may be disposed on opposite sides of each S/D region 124, and the fin sidewall spacers 123 may include the same material as the gate spacers 122. Portions of the gate stacks 140, the gate spacers 122, and the fin sidewall spacers 123 may be disposed on isolation regions 114. The isolation regions 114 are disposed on the substrate 102. The isolation regions 114 may include an insulating material such as an oxygen-containing material, a nitrogen-containing material, or a combination thereof. In some embodiments, the isolation regions 114 are shallow trench isolation (STI). The insulating material may be formed by a high-density plasma chemical vapor deposition (HDP-CVD), a flowable chemical vapor deposition (FCVD), or other suitable deposition process. In one aspect, the isolation regions 114 includes silicon oxide that is formed by a FCVD process.

As shown in FIGS. 1A and 1B, a contact etch stop layer (CESL) 126 is formed on the S/D regions 124 and the isolation region 114, and an interlayer dielectric (ILD) layer 128 is formed on the CESL 126. The CESL 126 can provide a mechanism to stop an etch process when forming openings in the ILD layer 128. The CESL 126 may be conformally deposited on surfaces of the S/D regions 124 and the isolation regions 114. The CESL 126 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be deposited by CVD, PECVD, ALD, or any suitable deposition technique. The ILD layer 128 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), organosilicate glass (OSG), SiOC, and/or any suitable low-k dielectric materials (e.g., a material having a dielectric constant lower than that of silicon dioxide), and may be deposited by spin-on, CVD, FCVD, PECVD, PVD, or any suitable deposition technique.

A conductive contact (not shown) may be disposed in the ILD layer 128 and over the S/D region 124. The conductive contact may be electrically conductive and include a material having one or more of Ru, Mo, Co, Ni. W, Ti, Ta, Cu, Al, TiN or TaN, and the conductive contact may be formed by any suitable method, such as electro-chemical plating (ECP), or PVD. A silicide layer (not shown) may be disposed between the conductive contact and the S/D region 124.

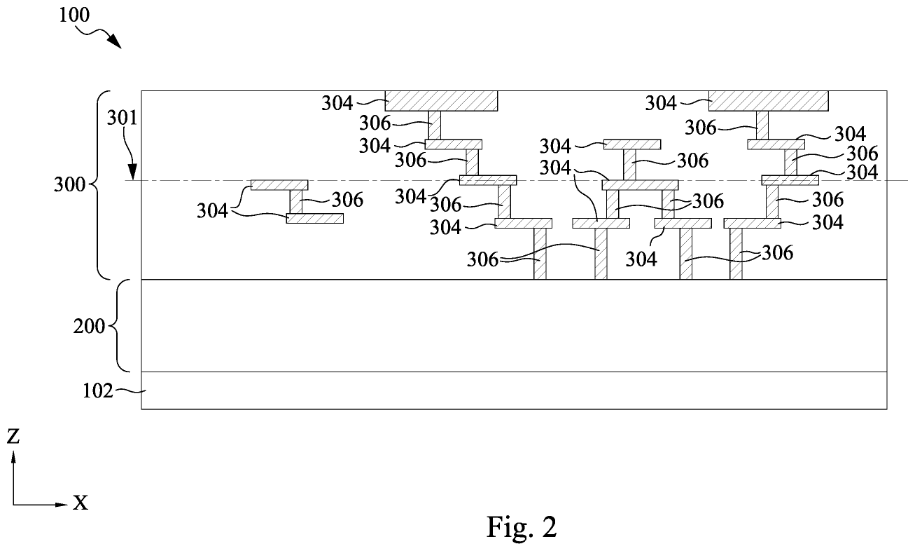

The semiconductor device structure 100 may further includes an interconnection structure 300 disposed over the devices 200 and the substrate 102, as shown in FIG. 2. The interconnection structure 300 includes various conductive features, such as a first plurality of conductive features 304 and second plurality of conductive features 306, and an intermetal dielectric (IMD) layer 302 to separate and isolate various conductive features 304, 306. In some embodiments, the first plurality of conductive features 304 are conductive lines and the second plurality of conductive features 306 are conductive vias. The interconnection structure 300 includes multiple levels of the conductive features 304, and the conductive features 304 are arranged in each level to provide electrical paths to various devices 200 disposed below. The conductive features 306 provide vertical electrical routing from the devices 200 to the conductive features 304 and between conductive features 304. For example, the bottom-most conductive features 306 of the interconnection structure 300 may be electrically connected to the conductive contacts disposed over the S/D regions 124 (FIG. 1B) and the gate electrode layer 138 (FIG. 1B). The conductive features 304 and conductive features 306 may be made from one or more electrically conductive materials, such as metal, metal alloy, metal nitride, or silicide. For example, the conductive features 304 and the conductive features 306 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, iridium, other suitable conductive material, or a combination thereof.

The IMD layer 302 includes one or more dielectric materials to provide isolation functions to various conductive features 304, 306. The IMD layer 302 may include multiple dielectric layers embedding multiple levels of conductive features 304, 306. The IMD layer 302 is made from a dielectric material, such as SiOₓ, SiOₓC_{y}H_{z}, SiOCN, SiON, or SiOₓC_{y}, where x, y and z are integers or non-integers. In some embodiments, the IMD layer 302 includes a low-k dielectric material having a k value less than that of silicon dioxide.

In some embodiments, the conductive features 304 disposed in a level of the interconnect structure 300 are partially overlapping with respect to the x-axis, which is substantially parallel to a major surface of the substrate 102, as shown in FIG. 2. A level of the interconnect structure 300 may be a layer of the IMD layer 302. The partially overlapping conductive features 304 with respect to the x-axis may decrease the parasitic capacitance effect as the adjacent conductive features 304 are getting closer, which leads to improved electrical performance, such as improved reliability and reduced propagation delay and extra noise. For example, a top surface of one or more conductive features 304 disposed in a level of the interconnect structure 300 may be at a plane 301 extending along the x-axis, and the plane 301 may be between a top surface and a bottom surface of other conducive features 304 disposed in the level of the interconnect structure 300. The partially overlapping conductive features 304 are described in detail below. Additional materials, such as glue layers, etch stop layers, and barrier layers, may be included in the interconnect structure 300 but are not shown in FIG. 2 for clarity.

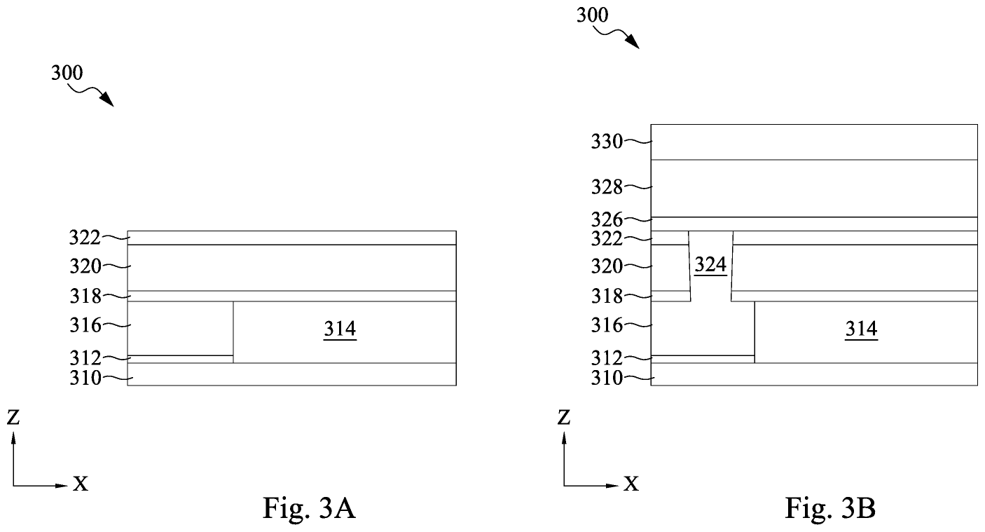

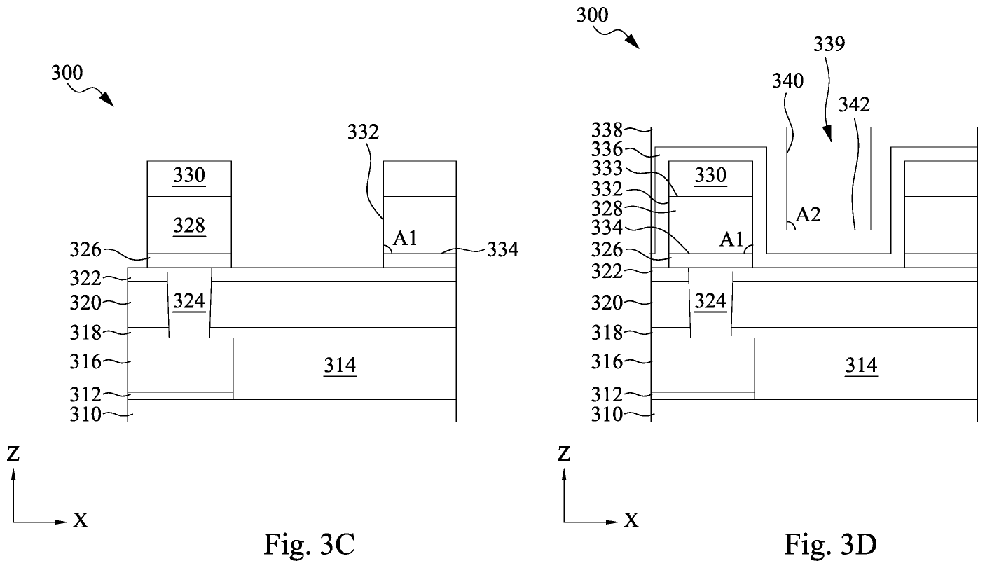

FIGS. 3A-3D are cross-sectional side views of various stages of manufacturing an interconnect structure 300, in accordance with some embodiments. As shown in FIG. 3A, the interconnect structure 300 includes a dielectric layer 310, which may be an ILD layer or an IMD layer. For example, the dielectric layer 310 may be the ILD layer 128 (FIGS. 1A and 1B) or the IMD layer 302 (FIG. 2). The dielectric layer 310 may include the same material as the ILD layer 128 or the IMD layer 302. In some embodiments, the dielectric layer 310 includes a low-k dielectric material, SiO₂, SiOC, SiON, SiOC, SiOCN, or other suitable dielectric material. In some embodiments, the low-k dielectric material includes SiOCH. The dielectric layer 310 may be formed by CVD, FCVD, ALD, spin coating, or other suitable process. One or more conductive features (not shown) are disposed in the dielectric layer 310. A dielectric layer 314 is disposed on the dielectric layer 310. The dielectric layer 314 may include the same material as the dielectric layer 310 and may be formed by the same process as the dielectric layer 310. One or more conductive features 316 (only one is shown) are formed in the dielectric layer 314. The conductive feature 316 includes an electrically conductive material, such as Cu, Co, Ru, Mo, Cr, W, Mn, Rh, Jr, Ni, Pd, Pt, Ag, Au, Al, Ta, TaN, TiN, alloys thereof, or other suitable material. The conductive feature 316 is formed by any suitable process, such as ECP, electroless deposition (ELD), PVD, or CVD. The conductive feature 316 may be the conductive feature 304 shown in FIG. 2. In some embodiments, a barrier layer (not shown) may be formed between the dielectric layer 314 and the conductive feature 316, and a liner (not shown) may be formed between the barrier layer and the conductive feature 306. The barrier layer and the liner may be formed by any suitable process, such as CVD, PECVD, or ALD. In some embodiments, a glue layer 312 is disposed between the conductive feature 316 and the dielectric layer 310 (or the conductive feature formed in the dielectric layer 310). The glue layer 312 may include Si, SiO, SiN, SiCN, SiON, SiOC, one or more metal nitrides, one or more metals, or other suitable material that can provide adhesion between the conductive feature 316 and the dielectric layer 310 and the conductive features (not shown) formed therein. The glue layer 312 may be formed by any suitable process, such as PVD, CVD, or ALD. The glue layer 312 may have a thickness ranging from about 5 angstroms to about 200 angstroms.

As shown in FIG. 3A, an etch stop layer 318, a dielectric layer 320, and a dielectric cap 322 are formed over the dielectric layer 314 and the conductive features 316. The etch stop layer 318 includes Si, SiO, SiN, SiC, SiON, SiOC, SiCN, one or more metal nitrides, one or more metal oxides, or other suitable material. The etch stop layer 318 may be a single layer or a multilayer structure. The etch stop layer 308 is formed by any suitable process, such as PVD, CVD, or ALD and may have a thickness ranging from about 5 angstroms to about 200 angstroms. The dielectric layer 320 may include the same material as the dielectric layer 310 and may be formed by the same process as the dielectric layer 310. The dielectric layer 320 has a thickness ranging from about 30 angstroms to about 1000 angstroms. The dielectric cap 322 includes SiO₂, SiOC, SiN, SiCN, SiON, SiOCN, or other suitable dielectric material. The dielectric cap 322 includes a material different from the material of the dielectric layer 320. The dielectric cap 322 provides a stop point for a subsequent planarization process. In some embodiments, the dielectric cap 322 has thickness ranging from about 20 angstroms to about 1000 angstroms.

As shown in FIG. 3B, a conductive feature 324 is formed in the etch stop layer 318, the dielectric layer 320, and the dielectric cap 322. The conductive feature 324 may be a conductive via. The conductive feature 324 includes the same material as the conductive feature 316. In some embodiments, an opening is formed in the etch stop layer 318, the dielectric layer 320, and the dielectric cap 322, and the conductive feature 324 is formed in the opening and on the dielectric cap 322. The portion of the conductive feature 324 formed on the dielectric cap 322 is subsequently removed by a planarization process, such as a chemical-mechanical polishing (CMP) process, and the planarization process stops at the dielectric cap 322, which has better mechanical strength than the dielectric layer 320.

Next, a glue layer 326, a conductive layer 328, and a cap layer 330 are formed over the dielectric cap 322 and the conductive feature 324. The glue layer 326 may include the same material as the glue layer 312 and may be formed by the same process as the glue layer 312. The conductive layer 328 may include the same material as the conductive feature 316. The cap layer 330 may include Si, SiO, SiN, SiON, SiOC, SiCN, one or more metal nitrides, one or more metal oxides, one or more metal carbides, one or more metals, or other suitable material. The cap layer 330 functions as a hardmask for patterning the conductive layer 328. The cap layer 330 has a thickness ranging from about 30 angstroms to about 1000 angstroms.

As shown in FIG. 3C, the cap layer 330, the conductive layer 328, and the glue layer 326 are patterned to form two or more portions of the cap layer 330, the conductive layer 328, and the glue layer 326. The patterning of the cap layer 330, the conductive layer 328, and the glue layer 326 is performed by one or more etch processes. In some embodiments, multiple reactive ion etching (RIE) processes are used. For example, the RIE process uses inductively coupled plasma (ICP), capacitively coupled plasma (CCP), or remote plasma with one or more etchants such as CH₄, CH₃F, CH₂F₂, CHF₃, C₄F₈, C₄F₆, CF₄, NF₃, H₂, HBr, CO, CO₂, O₂, BCl₃, Cl₂, N₂, He, Ne, and/or Ar. The chamber pressure ranges from about 0.2 mT to about 120 mT, and the processing temperature ranges from about 0 degrees Celsius to about 200 degrees Celsius. The plasma power ranges from about 50 W to about 3000 W, and a bias ranges from about 0 V to about 1200 V. In some embodiments, the patterning of the cap layer 330, the conductive layer 328, and the glue layer 326 may be performed by one or more wet etch processes.

As shown in FIG. 3C, each portion of the conductive layer 328 may be a conductive feature, such as a conductive line. Each portion of the conductive layer 328, or each conductive line, includes a sidewall 332 and a bottom 334. An angle A1 is formed between the sidewall 332 and the bottom 334. In some embodiments, the angle A1 ranges from about 45 degrees to about 135 degrees, such as from about 60 degrees to about 120 degrees. In some embodiments, the angle A1 is an acute angle. In some embodiments, the angle A1 is an obtuse angle. The angle A1 may be controlled by the etch process used to pattern the conductive layer 328.

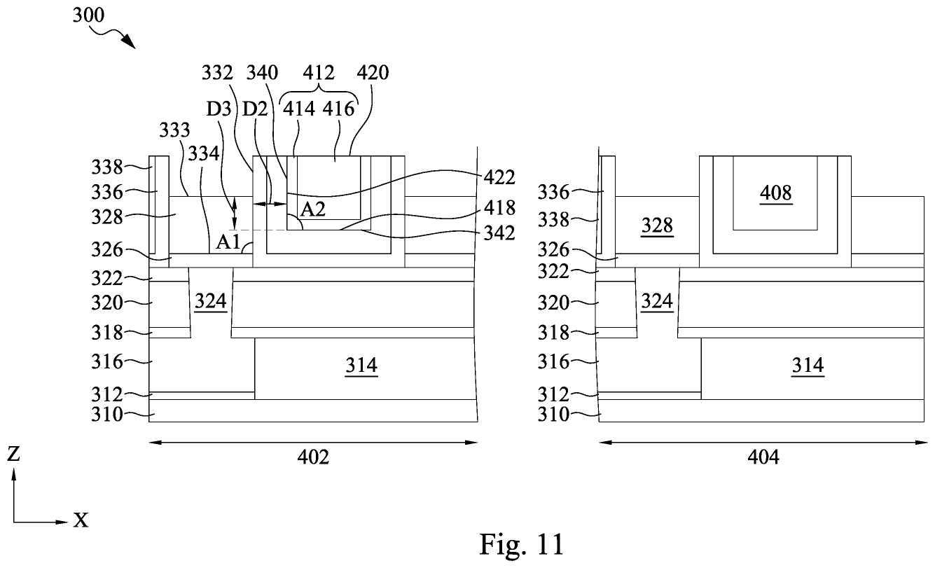

As shown in FIG. 3D, a protect layer 336 is formed on the patterned cap layer 330, conductive layer 328, and glue layer 326 and on the exposed portions of the dielectric cap 322. A dielectric spacer 338 is formed on the protect layer 336. The protect layer 336 includes a dielectric material, such as SiCN, SiO, SiN, SiC, SiON, SiOC, one or more metal nitrides, one or more metal oxides, or other suitable material. The protect layer 336 is used to protect the portions of the conductive layer 328 and to prevent metal diffusion of the portions of the conductive layer 328 into the dielectric spacer 338. The protect layer 336 has a thickness ranging from about 5 angstroms to about 200 angstroms. The protect layer 336 may be formed by a conformal process, such as an ALD process. The dielectric spacer 338 includes a low-k dielectric material, SiO₂, SiOC, SiON, SiOCN, or other suitable material. In some embodiments, the dielectric spacer 338 includes the same material as the dielectric layer 320. The dielectric spacer 338 has a thickness ranging from about 10 angstroms to about 500 angstroms. The dielectric spacer 338 may be formed by a conformal process, such as an ALD process. The thickness of the dielectric spacer 338 determines the location of a bottom of a conductive feature 412 (FIG. 11) in the z-axis, which is substantially perpendicular to a major surface of the substrate 102 (FIG. 2), in order to partially overlapping the portions of the conductive layer 328 with the conductive features 412 with respect to the x-axis. Partially overlapping of the portions of the conductive layer 328 and the conductive features 412 leads to decreased parasitic capacitance effect compared to fully overlapping of the portions of the conductive layer 328 and the conductive features 412. Thus, if the thickness of the dielectric spacer 338 is greater than about 500 angstroms, a bottom 418 (FIG. 11) of the conductive feature 412 may be disposed at a level over a top 333 of the portion of the conductive layer 328 in the z-axis, and there is no overlapping between the portions of the conductive layer 328 and the conductive features 412 in the x-axis. Furthermore, the distance between the two conductive features on the same level is too large in the z-axis to achieve the efficient performance improvement by the additional cost, since the original parasitic capacitance effect may be too small. In addition, no overlapping also leads to challenging via etch loading on the next level of conductive features. On the other hand, if the thickness of the dielectric spacer 338 is less than about 10 angstroms, the bottom 418 of the conductive feature 412 is too close to the bottom 334 of the portion of the conductive layer 328 in the z-axis, and there is not enough offset of the portions of the conductive layer 328 and the conductive features 412 in the x-axis to reduce the parasitic capacitance effect. Furthermore, an opening 339 is formed between adjacent portions of the conductive layer 328, and the thickness of the dielectric spacer 338 defines the width in the x-axis of the opening 339. Thus, if the thickness of the dielectric spacer 338 is greater than about 500 angstroms, the opening 339 may not exist. On the other hand, if the thickness of the dielectric spacer 338 is less than about 10 angstroms, the width of the conductive feature 412 subsequently formed in the opening 339 may be unnecessarily large.

As shown in FIG. 3D, a portion of the dielectric spacer 338 disposed between adjacent portions of the conductive layer 328 has a sidewall 340 and a bottom 342, which define the opening 339. In some embodiments, the sidewall 340 is substantially parallel to the sidewall 332 of the portion of the conductive layer 328, and the bottom 342 is substantially parallel to the bottom 334 of the portion of the conductive layer 328. An angle A2 is formed between the sidewall 340 and the bottom 342 of the dielectric spacer 338. Because the sidewall 340 is substantially parallel to the sidewall 332, and the bottom 342 is substantially parallel to the bottom 334 and extends in opposite direction as the bottom 334, the angles A1 and A2 may be supplementary. In other words, the sum of angles A1 and A2 may be about 180 degrees. For example, the angle A1 may be an acute angle, the angle A2 may be an obtuse angle, and the sum of angles A1 and A2 is about 180 degrees. In another example, the angle A1 may be an obtuse angle, the angle A2 may be an acute angle, and the sum of angles A1 and A2 is about 180 degrees.

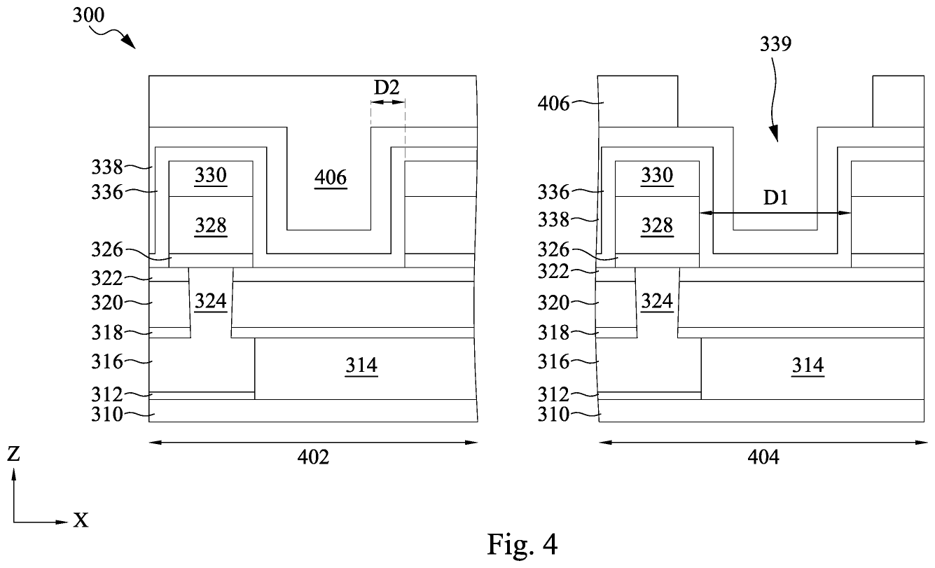

FIGS. 4-13 are cross-sectional side views of various stages of manufacturing the interconnect structure 300, in accordance with some embodiments. As shown in FIG. 4, the interconnect structure 300 includes a region 402 and a region 404. In the region 404, the distance D1 between conductive features, such as between the portions of the conductive layer 328, is substantially greater than the distance D2 between conductive features, such as between the portion of the conductive layer 328 and the subsequently formed conductive feature 412 (FIG. 11). In other words, conductive feature density in the region 402 is substantially greater than the conductive feature density in the region 404. As shown in FIG. 4, a photoresist layer 406 is formed in the regions 402, 404. The photoresist layer 406 fills the openings 339 in the region 402, while the openings 339 in the region 404 are exposed.

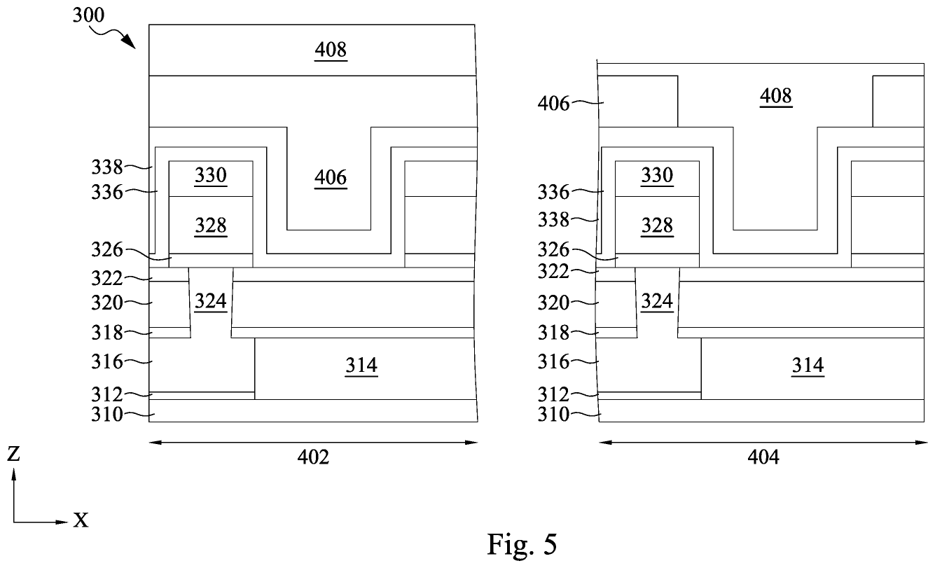

As shown in FIG. 5, a dielectric fill material 408 is formed in the opening 339 in the region 404. The dielectric fill material 408 includes a material different from the dielectric spacer 338 and the photoresist layer 406. The dielectric fill material 408 includes SiOₓ, SiOC, SiCN, SiON, SiC, or other suitable material. The dielectric fill material 408 may be also formed on the photoresist layer 406 in regions 402, 404.

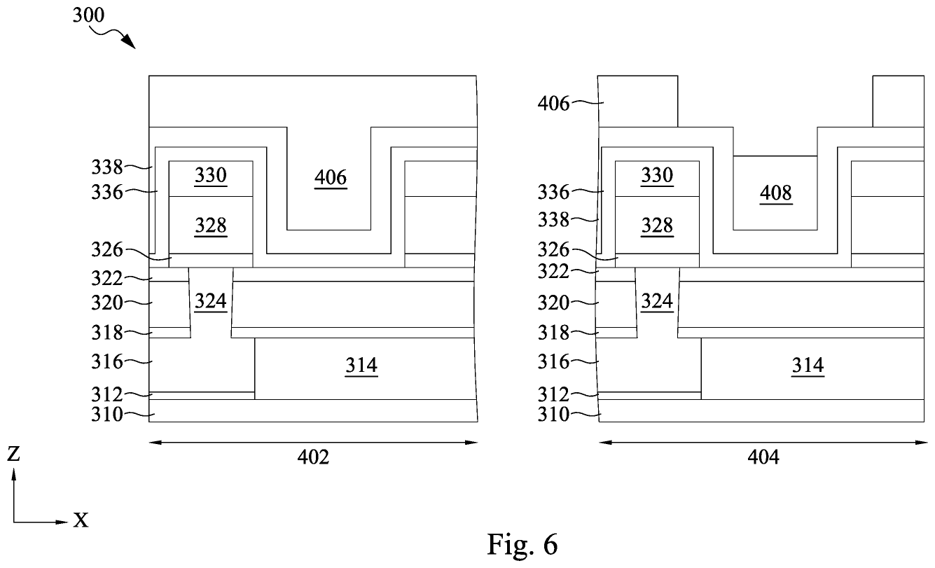

As shown in FIG. 6, the dielectric fill material 408 is recessed to a level at or below a level of a top surface of the dielectric spacer 338 in region 404, and the portion of the dielectric fill material 408 disposed on the photoresist layer 406 in region 402 is removed. The recessing of the dielectric fill material 408 may be performed by a selective etch process that does not substantially affect the photoresist layer 406 and the dielectric spacer 338. The remaining dielectric fill material 408 in region 404 may completely or partially fill the opening 339 (FIG. 4). In some embodiments, the remaining dielectric fill material 408 has a thickness in the z-axis ranging from about 30 angstroms to about 1000 angstroms.

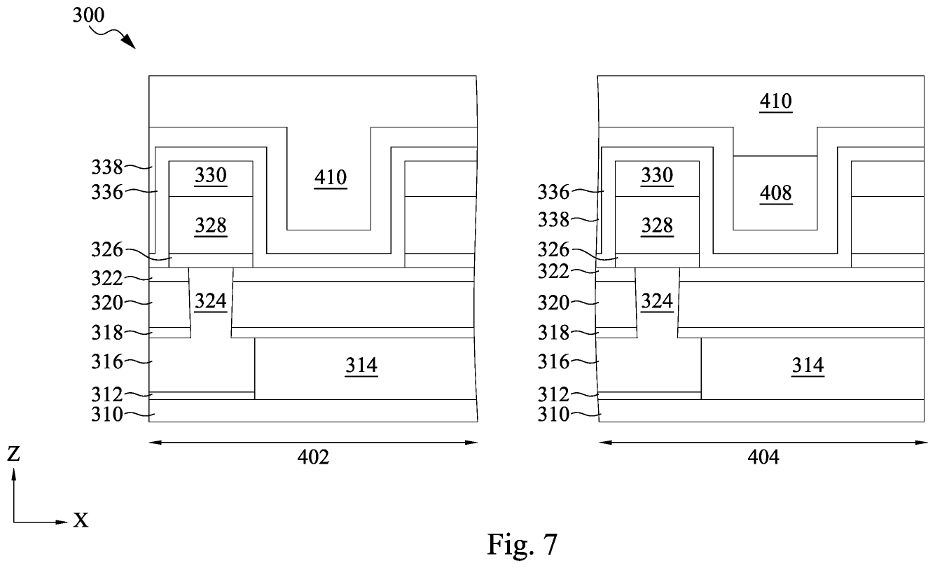

As shown in FIG. 7, the photoresist layer 406 in both regions 402, 404 is removed, and another dielectric fill material 410 is formed in the opening 339 in the region 402 and on the dielectric fill material 408 in the region 404. The dielectric fill material 410 includes a material different from the dielectric spacer 338, the dielectric fill material 408, and the photoresist layer 406. The dielectric fill material 410 includes carbon, SiN, SiCN, SiC, one or more metal nitrides, one or more metal carbides, one or more metal oxides, or other suitable material. In some embodiments, the dielectric fill material 410 includes the same material as the photoresist layer 406. The dielectric fill material 410 may be also formed on the dielectric spacer 338 in regions 402, 404.

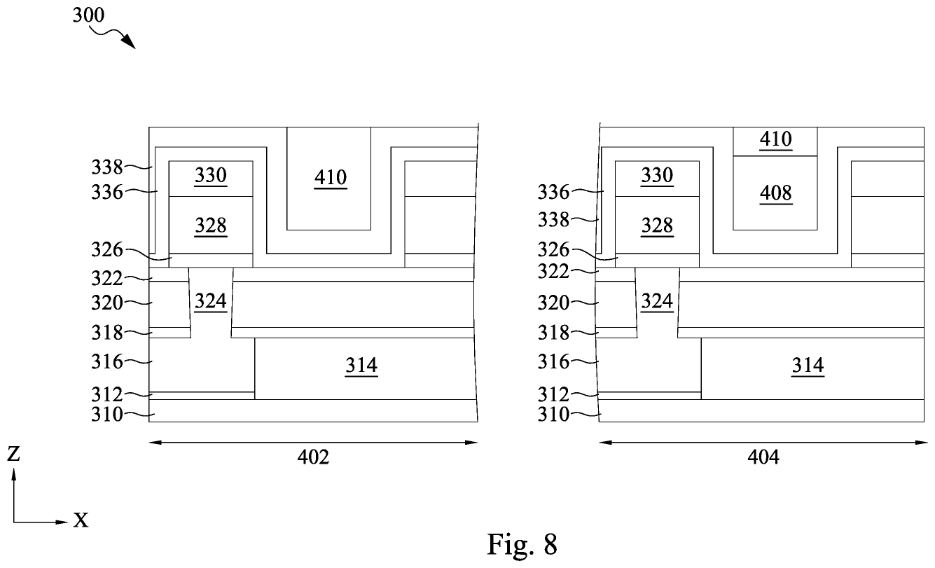

As shown in FIG. 8, the dielectric fill material 410 is recessed. In some embodiments, the portions of the dielectric fill material 410 disposed on the dielectric spacer 338 in regions 402, 404 are removed. The removal of the portions of the dielectric fill material 410 may be performed by any suitable process. In some embodiments, a selective etch process is performed to remove the portions of the dielectric fill material 410 without substantially affect the dielectric spacer 338. In some embodiments, a planarization process is performed to remove the portions of the dielectric fill material 410. As a result, the remaining portion of the dielectric fill material 410 is disposed between adjacent portions of the conductive layer 328 in region 402, and the dielectric fill material 408 and the dielectric fill material 410 (if the dielectric fill material 408 did not fill the opening 339) are disposed between adjacent portions of the conductive layer 328, as shown in FIG. 8. In some embodiments, the dielectric fill material 408 completely fills the opening 339, and there is no dielectric fill material 410 disposed between adjacent portions of the conductive layer 328 in region 404.

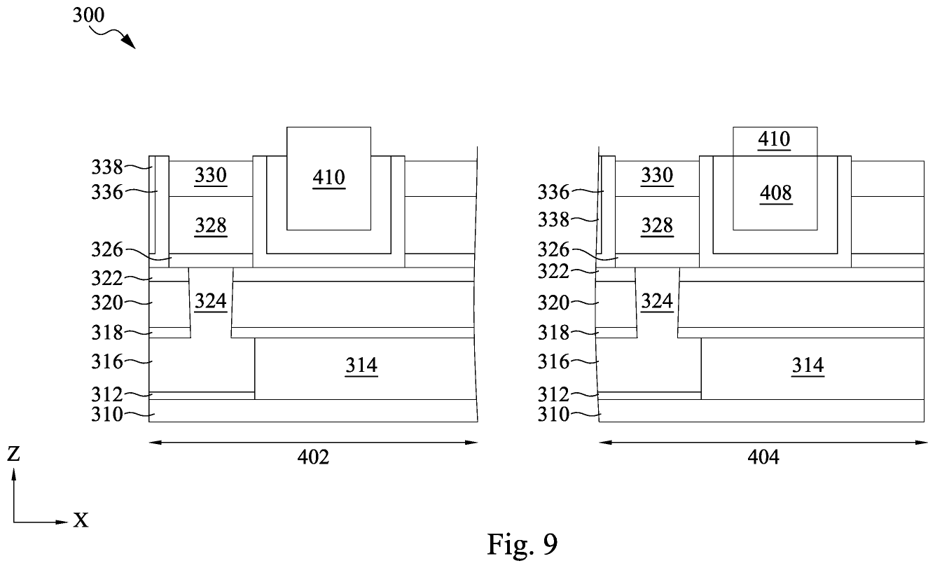

As shown in FIG. 9, portions of the dielectric spacer 338 and portions of the protect layer 336 are removed to expose the cap layer 330 in the regions 402, 404. In some embodiments, one or more dry or wet processes are used. For example, in some embodiments, a dry etch process uses inductively coupled plasma (ICP), capacitively coupled plasma (CCP), or remote plasma with one or more etchants such as CH₄, CH₃F, CH₂F₂, CHF₃, C₄F₈, C₄F₆, CF₄, H₂, HBr, CO, CO₂, O₂, BCl₃, Cl₂, N₂, He, Ne, and/or Ar. In some embodiments, one or more wet clean processes are performed to remove the portions of the dielectric spacer 338 and the portions of the protect layer 336. In some embodiments, one or more non-plasma chemical etch processes are performed to remove the portions of the dielectric spacer 338 and the portions of the protect layer 336. Because the materials of the dielectric spacer 338 and the protect layer 336 are different from the materials of the cap layer 330 and the dielectric fill materials 410, 408 (if the portion of the dielectric fill material 410 is not formed on the dielectric fill material 408 in the region 404), the cap layer 330 and the dielectric fill materials 410, 408 are not substantially affected by the removal of the portions of the dielectric spacer 338 and the portions of the protect layer 336.

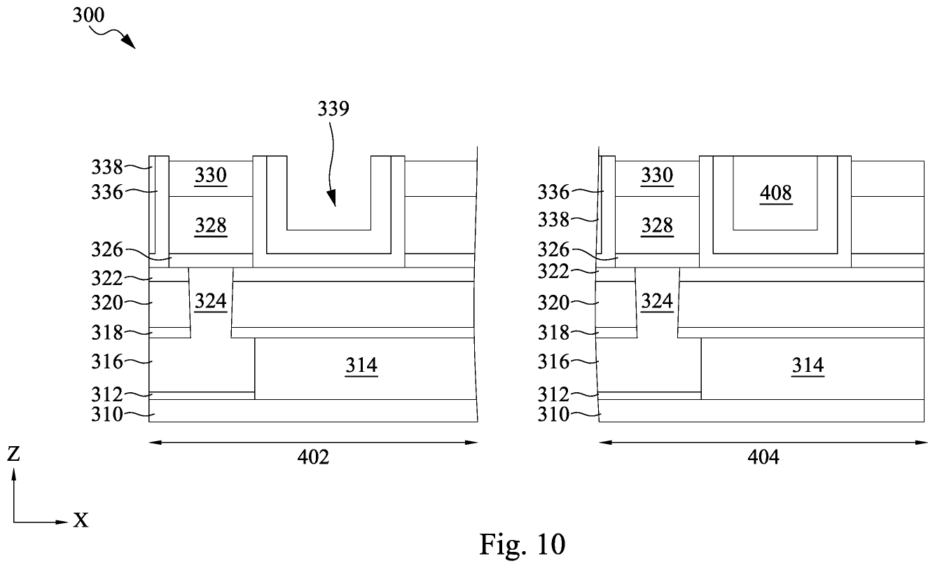

As shown in FIG. 10, the dielectric fill material 410 is removed in the regions 402, 404. The removal of the dielectric fill material 410 may be performed by any suitable process. In some embodiments, the dielectric fill material 410 is removed by a wet clean process, a non-plasma chemical etch process, a baking process, or a plasma etch process. Because the material of the dielectric fill material 410 is different from the materials of the cap layer 330, the dielectric spacer 338, the protect layer 336, and the dielectric fill material 408, the cap layer 330, the dielectric spacer 338, the protect layer 336, and the dielectric fill material 408 are not substantially affected by the removal of the dielectric fill material 410. As the result of the removal of the dielectric fill material 410, the opening 339 reappeared in the region

As shown in FIG. 11, a conductive feature 412 is formed in the opening 339 in the region 402. In some embodiments, the conductive feature 412 includes a barrier layer 414 and a conductive fill material 416. In some embodiments, the conductive fill material 416 includes a metal that is not susceptible to diffusion, and the barrier layer 414 is not present. The barrier layer 414 includes any suitable material, such as metal nitride, metal oxide, metal carbide, metal, or combinations thereof. The barrier layer 414 has a thickness ranging from about 5 angstroms to about 200 angstroms. The conductive fill material 416 includes an electrically conductive material, such as Cu, Co, Ru, Mo, Cr, W, Mn, Rh, Jr, Ni, Pd, Pt, Ag, Au, Al, Ta, TaN, TiN, alloys thereof, or other suitable material. In some embodiments, the conductive fill material 416 includes the same material as the conductive layer 328. In some embodiments, the conductive fill material 416 include a material different than the material of the conductive layer 328. The conductive feature 412 may be formed in the opening 339 in the region 402 and on the dielectric spacer 338, the protect layer 336, and the cap layer 330 in the regions 402, 404. A planarization process, such as a CMP process, may be performed to remove the portions of the conductive feature 412 formed on the dielectric spacer 338, the protect layer 336, and the cap layer 330 in the regions 402, 404. Next, the cap layer 330 in the regions 402, 404 is removed by any suitable process. In some embodiments, the cap layer 330 is removed by a wet clean process, a non-plasma chemical etch process, or a plasma etch process. The material of the cap layer 330 is different from the materials of the dielectric spacer 338, the protect layer 336, the barrier layer 414, the conductive fill material 416, and the dielectric fill material 408, and the removal of the cap layer 330 does not substantially affect the dielectric spacer 338, the protect layer 336, the barrier layer 414, the conductive fill material 416, and the dielectric fill material 408.

As shown in FIG. 11, the conductive feature 412 includes a bottom 418, a top 420, and a sidewall 422. In some embodiments, the barrier layer 414 is present, the bottom 418 and the sidewall 422 include the barrier layer 414, and the top 420 includes both the barrier layer 414 and the conductive fill material 416. In some embodiments, the barrier layer 414 is not present, and the bottom 418, the top 420, and the sidewall 422 include the conductive fill material 416. Each portion of the conductive layer 328 includes the bottom 334, the top 333, and the sidewall 332. The angle A1 is defined between the sidewall 332 and the bottom 334. The angle A2 is defined by the sidewall 340 and the bottom 342 of the dielectric spacer 338. Because the sidewall 422 of the conductive feature 412 is in contact with the sidewall 340 of the dielectric spacer 338, the bottom 418 of the conductive feature 412 is in contact with the bottom 342 of the dielectric spacer 338, the angle A2 is also defined by the sidewall 422 and the bottom 418 of the conductive feature 412. Thus, in some embodiments, an angle, such as the angle A1, formed between the sidewall, such as the sidewall 332, and the bottom, such as the bottom 334, of a conductive feature, such as the portion of the conductive layer 328, is substantially different from another angle, such as the angle A2, formed between the sidewall, such as the sidewall 422, and the bottom, such as the bottom 418, of an adjacent conductive feature, such as the conductive feature 412. In some embodiments, the angle A1 is an acute angle and the angle A2 is an obtuse angle. In some embodiments, the angle A1 is an obtuse angle and the angle A2 is an acute angle. In some embodiments, both angles A1 and A2 are substantially 90 degrees. In some embodiments, the angles A1 and A2 are supplementary.

As shown in FIG. 11, a conductive feature, such as the portion of the conductive layer 328, and the adjacent conductive feature 412 are partially overlapping in the x-axis in the region 402. In other words, the conductive features in the region 402 are vertically asymmetrical. For example, the top 333 of the portion of the conductive layer 328 is at a level in the z-axis between the top 420 and the bottom 418 of the conductive feature 412, and the bottom 418 of the conductive feature 412 is at a level in the z-axis between the top 333 and the bottom 334 of the portion of the conductive layer 328. In some embodiments, a distance D3 in the z-axis between the top 333 of the portion of the conductive layer 328 and the bottom 418 of the conductive feature 412 ranges from about 25 percent of the height of the portion of the conductive layer 328 in the z-axis to about 95 percent of the height of the portion of the conductive layer 328. If the distance D3 is greater than about 95 percent of the height of the conductive feature 412, there is not enough offset of the portions of the conductive layer 328 and the conductive features 412 in the x-axis to reduce the parasitic capacitance effect. On the other hand, if the distance D3 is less than about 25 percent of the height of the conductive feature 412, the portions of the conductive layer 328 and the conductive features 412 are almost formed in different layers. Furthermore, as described above, if the distance D3 is less than about 25 percent, it may attribute to challenging via etch loading on the next level of conductive features.

As described in FIG. 4, the distance D2 between the portion of the conductive layer 328 and the conductive feature 412 is relatively small, such as about 0.5 to about 1.5 times the width of the conductive feature 412. With the partially overlapping adjacent conductive features, parasitic capacitance effect is reduced. In the region 404 where the distance D1 between the portions of the conductive layer 328 being 1.5 to 10 times the width of the portion of the conductive layer 328, there is no need to overlapping the portions of the conductive layer 328 because the parasitic capacitance effect is relatively low. Thus, the conductive features, such as the portions of the conductive layer 328, disposed in the region 404 are aligned in the x-axis. In other words, the conductive features in the region 404 are vertically symmetrical.

As shown in FIG. 11, the bottoms 334 of the portions of the conductive layer 328 are disposed at the same level along the z-axis, and the bottoms 418 of the conductive features 412 are disposed at the same level along the z-axis. Thus, the offset of the portion of the conductive layer 328 and the conductive feature 412 in the x-axis is consistent, which leads to improved electric performance control. Because the processes do not include removing dielectric materials to form an opening and then form the conductive feature in the opening, there is no trench depth loading difference, which also improves electric performance control. Furthermore, as shown in FIG. 11, both vertically symmetrical and vertically asymmetrical conductive features can be formed in the same level, which leads to more options for patterning design.

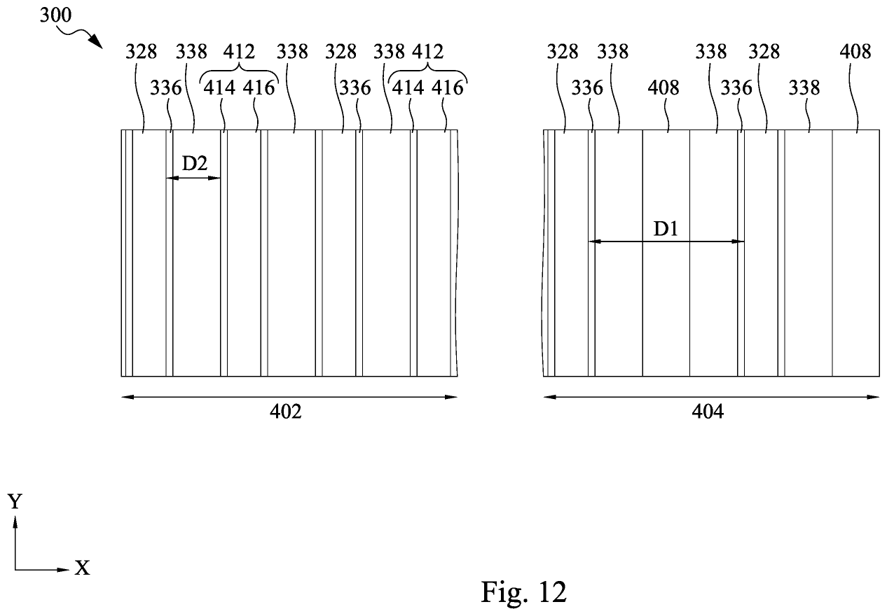

FIG. 12 is a top view of the interconnect structure 300 shown in FIG. 11, in accordance with some embodiments. As shown in FIG. 12, the conductive feature density is greater in the region 402 than in the region 404. The distance D2 between adjacent conductive features, such as the portion of the conductive layer 328 and adjacent conductive feature 412, in the region 402 is substantially less than the distance D1 between adjacent conductive features, such as the adjacent portions of the conductive layer 328, in the region 404. In some embodiments, the portions of the conductive layer 328 and the conductive features 412 are conductive lines, such as the conductive features 304 shown in FIG. 2.

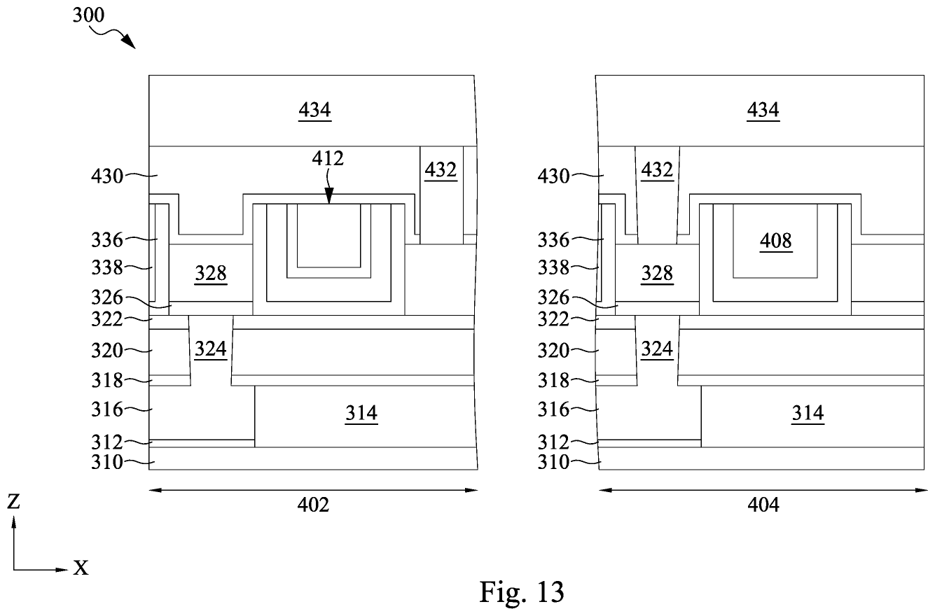

FIG. 13 is a cross-sectional side view of one of various stages of manufacturing the interconnect structure 300, in accordance with some embodiments. As shown in FIG. 13, after forming the conductive feature 412 in the region 402 and removing the cap layer 330 in the regions 402, 404, an etch stop layer 428 is formed on the exposed surfaces in the regions 402, 404, a dielectric layer 430 is formed on the etch stop layer 428, conductive features 432 are formed in the dielectric layer 430, and a conductive layer 434 is formed on the dielectric layer 430. The etch stop layer 428 may include the same material as the etch stop layer 318, the dielectric layer 430 may include the same material as the dielectric spacer 338, the conductive feature 432 may include the same material as the conductive feature 324, and the conductive layer 434 may include the same material as the conductive layer 328, the conductive feature 412, or the conductive feature 316. The conductive features 432 may be conductive vias, such as the conductive features 306 shown in FIG. 2. The conductive features 432 are in contact with corresponding portions of the conductive layer 328, and the conductive layer 434 is in contact with the conductive features 432. Additional processes may be performed on the conductive layer 434 to form portions of the conductive layer 434 disposed in a dielectric layer.

FIG. 13 shows multiple levels of dielectric material having conductive features formed therein. Each level may be an IMD layer, such as the IMD layer 302 shown in FIG. 2, including conductive features, such as the conductive features 304 or 306 as shown in FIG. 2. In at least one level, the conductive features, such as the portion of the conductive layer 328 and the adjacent conductive feature 412, are partially overlapping in the x-axis. In other words, the conductive features disposed in a level of IMD layer is vertically asymmetric. Furthermore, the IMD layer includes more than one dielectric materials, such as the dielectric spacer 338 and the dielectric fill material 408.

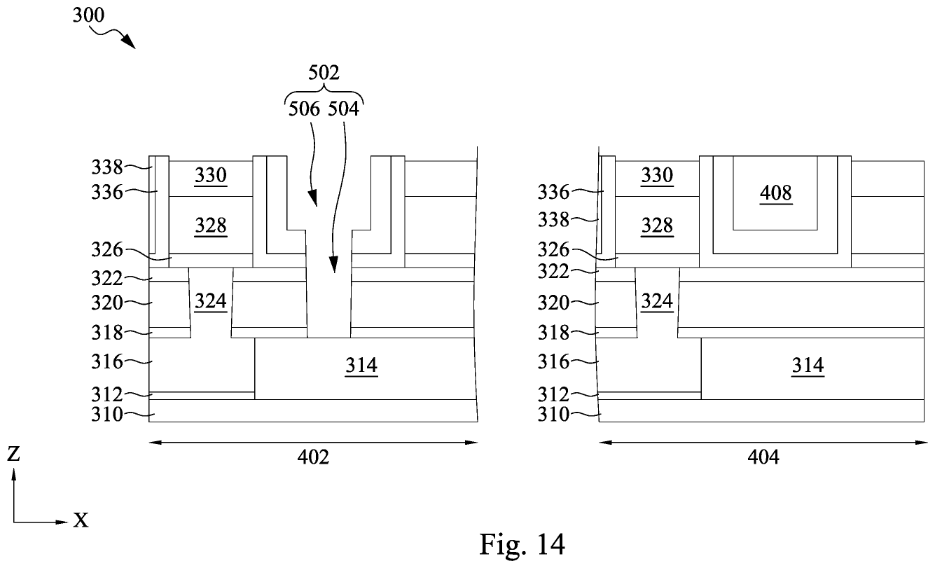

FIGS. 14-17 are cross-sectional side views of various stages of manufacturing the interconnect structure 300, in accordance with alternative embodiments. As shown in FIG. 14, after removing the dielectric fill material 410, an opening 502 is formed instead of the opening 339 (FIG. 10). In some embodiments, the opening 502 is formed before the removal of the dielectric fill material 410. The opening 502 includes a via portion 504 and a trench portion 506. The trench portion 506 may be the same as the opening 339. A portion of a conductive feature (not shown) disposed in the dielectric layer 314 is disposed in the via portion 504 of the opening 502.

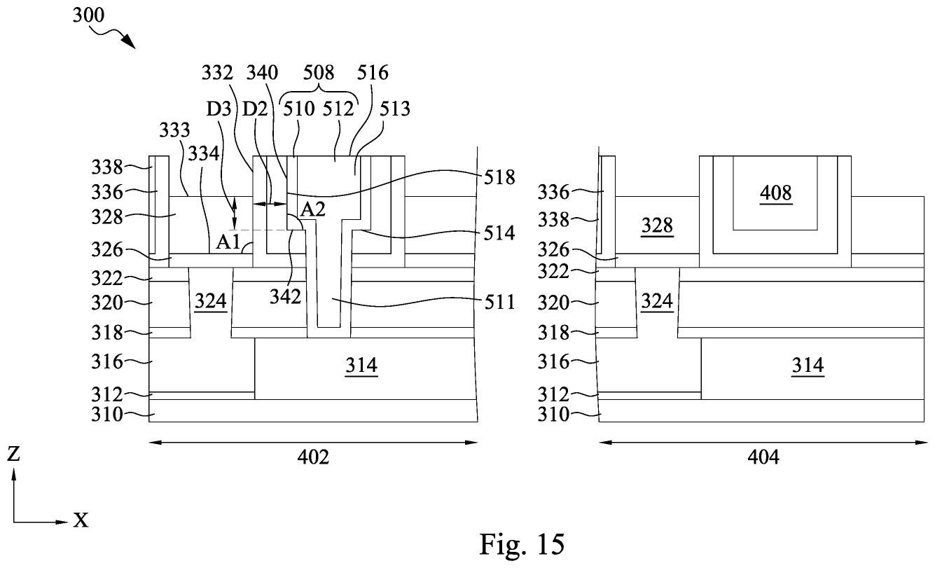

As shown in FIG. 15, a conductive feature 508 is formed in the opening 502 in the region 402. In some embodiments, the conductive feature 508 includes a barrier layer 510 and a conductive fill material 512. In some embodiments, the conductive fill material 512 includes a metal that is not susceptible to diffusion, and the barrier layer 510 is not present. The barrier layer 510 may include the same material as the barrier layer 414, and the conductive fill material 512 may include the same material as the conductive fill material 416. The conductive feature 508 is a dual-damascene structure that includes a conductive via portion 511 and a conductive line portion 513 disposed on the conductive via portion 511. The conductive feature 508 may be formed in the opening 502 in the region 402 and on the dielectric spacer 338, the protect layer 336, and the cap layer 330 in the regions 402, 404. A planarization process, such as a CMP process, may be performed to remove the portions of the conductive feature 508 formed on the dielectric spacer 338, the protect layer 336, and the cap layer 330 in the regions 402, 404. Next, the cap layer 330 in the regions 402, 404 is removed by any suitable process.

As shown in FIG. 15, the conductive line portion 513 includes a bottom 514, a top 516, and a sidewall 518. In some embodiments, the barrier layer 510 is present, the bottom 514 and the sidewall 518 include the barrier layer 510, and the top 516 includes both the barrier layer 510 and the conductive fill material 512. In some embodiments, the barrier layer 510 is not present, and the bottom 514, the top 516, and the sidewall 518 include the conductive fill material 512. Each portion of the conductive layer 328 includes the bottom 334, the top 333, and the sidewall 332. The angle A1 is defined between the sidewall 332 and the bottom 334. The angle A2 is defined by the sidewall 340 and the bottom 342 of the dielectric spacer 338. Because the sidewall 518 of the conductive line portion 513 is in contact with the sidewall 340 of the dielectric spacer 338, the bottom 514 of the conductive line portion 513 is in contact with the bottom 342 of the dielectric spacer 338, the angle A2 is also defined by the sidewall 518 and the bottom 514 of the conductive line portion 513. Thus, in some embodiments, an angle, such as the angle A1, formed between the sidewall, such as the sidewall 332, and the bottom, such as the bottom 334, of a conductive feature, such as the portion of the conductive layer 328, is substantially different from another angle, such as the angle A2, formed between the sidewall, such as the sidewall 518, and the bottom, such as the bottom 514, of an adjacent conductive feature, such as the conductive line portion 513. In some embodiments, the angle A1 is an acute angle and the angle A2 is an obtuse angle. In some embodiments, the angle A1 is an obtuse angle and the angle A2 is an acute angle. In some embodiments, both angles A1 and A2 are substantially 90 degrees. In some embodiments, the angles A1 and A2 are supplementary.

As shown in FIG. 15, a conductive feature, such as the portion of the conductive layer 328, and the adjacent conductive line portion 513 are partially overlapping in the x-axis in the region 402. In other words, the conductive features in the region 402 are vertically asymmetrical. For example, the top 333 of the portion of the conductive layer 328 is at a level in the z-axis between the top 516 and the bottom 514 of the conductive line portion 513, and the bottom 514 of the conductive line portion 513 is at a level in the z-axis between the top 333 and the bottom 334 of the portion of the conductive layer 328. In some embodiments, the distance D3 in the z-axis is between the top 333 of the portion of the conductive layer 328 and the bottom 514 of the conductive line portion 513.

As described in FIG. 4, the distance D2 between the portion of the conductive layer 328 and the conductive line portion 513 is relatively small, such as about 0.5 to about 1.5 times the width of the conductive line portion 513. With the partially overlapping adjacent conductive features, parasitic capacitance effect is reduced. In the region 404 where the distance D1 between the portions of the conductive layer 328 being 1.5 to 10 times the width of the portion of the conductive layer 328, there is no need to overlapping the portions of the conductive layer 328 because the parasitic capacitance effect is relatively low.

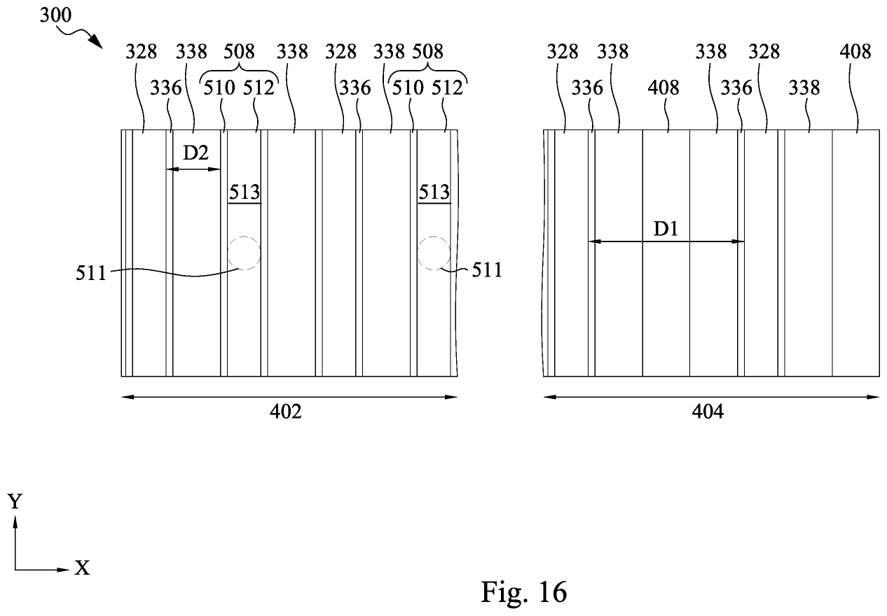

FIG. 16 is a top view of the interconnect structure 300 shown in FIG. 15, in accordance with alternative embodiments. As shown in FIG. 16, the conductive feature 508 includes the conductive line portion 513 and the conductive via portion 511 disposed below the conductive line portion 513.

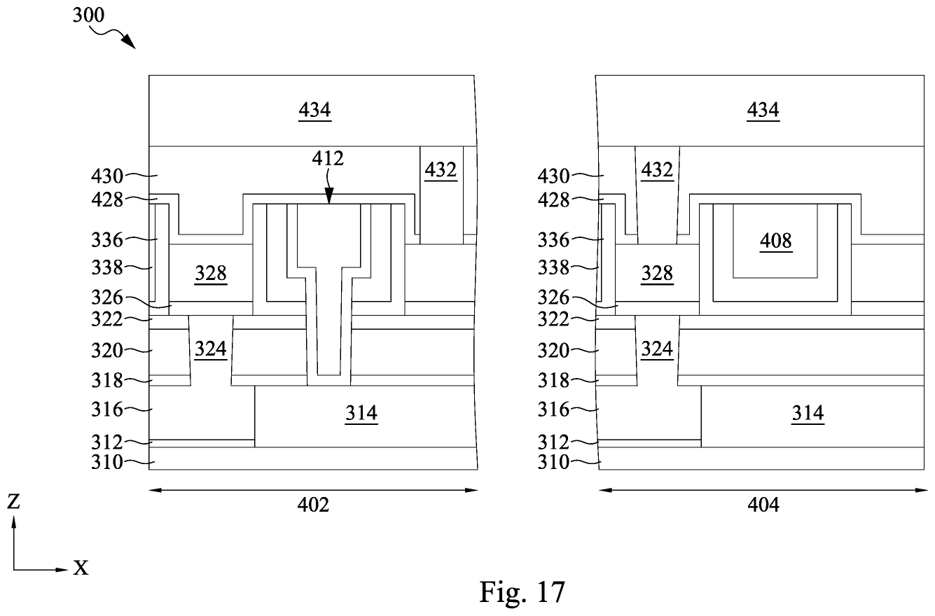

As shown in FIG. 17, the etch stop layer 428 is formed on the exposed surfaces in the regions 402, 404, the dielectric layer 430 is formed on the etch stop layer 428, the conductive features 432 are formed in the dielectric layer 430, and the conductive layer 434 is formed on the dielectric layer 430. Additional processes may be performed on the conductive layer 434 to form portions of the conductive layer 434 disposed in a dielectric layer.

The present disclosure in various embodiments provides an interconnect structure and methods of forming the same. In some embodiments, the interconnect structure includes conductive features that are partially overlapping in an axis substantially parallel to a major surface of a substrate disposed therebelow. Some embodiments may achieve advantages. For example, the partially overlapping conductive features lead to reduced parasitic capacitance effect, which leads to improved electrical performance.

An embodiment is an interconnect structure. The structure includes a dielectric layer, a first conductive feature disposed in the dielectric layer, and a second conductive feature disposed over the first conductive feature. The second conductive feature includes a first sidewall, a first bottom, and a first angle between the first sidewall and the first bottom. The structure further includes a third conductive feature disposed over the dielectric layer and adjacent the second conductive feature. The third conductive feature includes a second sidewall, a second bottom, and a second angle between the second sidewall and the second bottom, the second angle is substantially different from the first angle, and the second and third conductive features are partially overlapping in an axis substantially parallel to a major surface of the substrate.

Another embodiment is an interconnect structure. The structure includes a dielectric layer, a first conductive feature disposed in the dielectric layer, and a second conductive feature disposed over the first conductive feature. The second conductive feature includes a first top and a first bottom. The structure further includes a third conductive feature disposed over the dielectric layer and adjacent the second conductive feature. The third conductive feature includes a second top and a second bottom, the first top of the second conductive feature is located at a first level between the second top and the second bottom of the third conductive feature, and the second bottom of the third conductive feature is located at a second level between the first top and the first bottom of the second conductive feature.

A further embodiment is an interconnect structure. The structure includes a first dielectric layer, a first conductive line disposed in the first dielectric layer, a second dielectric layer disposed over the first dielectric layer and the first conductive layer, a conductive via disposed in the second dielectric layer, and a second conductive line disposed over the conductive via. The second conductive line includes a first top and a first bottom. The structure further includes an etch stop layer disposed on the second conductive line and a conductive feature extending from the etch stop layer to the first dielectric layer. The conductive feature includes a conductive line portion and a conductive via portion, and the conductive line portion includes a second bottom located at a level between the first top and the first bottom of the second conductive line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An interconnect structure disposed over a substrate, comprising:
a dielectric layer;
a first conductive feature disposed in the dielectric layer;
a second conductive feature disposed over the first conductive feature, wherein the second conductive feature comprises a first sidewall, a first bottom, and a first angle between the first sidewall and the first bottom; and
a third conductive feature disposed over the dielectric layer and adjacent the second conductive feature, wherein the third conductive feature comprises a second sidewall, a second bottom, and a second angle between the second sidewall and the second bottom, the second angle is substantially different from the first angle, and wherein the second and third conductive features are partially overlapping in an axis substantially parallel to a major surface of the substrate.

2. The interconnect structure of claim 1, wherein the third conductive feature further comprises a barrier layer and a conductive fill material.

3. The interconnect structure of claim 2, wherein the conductive fill material and the second conductive feature comprise different materials.

4. The interconnect structure of claim 2, further comprising a glue layer disposed between the first conductive feature and the second conductive feature.

5. The interconnect structure of claim 4, further comprising a dielectric spacer disposed between the second and third conductive features and between the third conductive feature and the dielectric layer.

6. The interconnect structure of claim 5, further comprising a protect layer disposed between the second conductive feature and the dielectric spacer and between the dielectric layer and the dielectric spacer.

7. The interconnect structure of claim 6, further comprising a cap layer disposed between the protect layer and the dielectric layer.

8. The interconnect structure of claim 1, wherein the first angle is an acute angle, and the second angle is an obtuse angle.

9. The interconnect structure of claim 1, wherein the first angle is an obtuse angle, and the second angle is an acute angle.

10. The interconnect structure of claim 1, wherein the first and second angles are supplementary.

11. An interconnect structure disposed over a substrate, comprising:
a dielectric layer;
a first conductive feature disposed in the dielectric layer;
a second conductive feature disposed over the first conductive feature, wherein the second conductive feature comprises a first top and a first bottom; and
a third conductive feature disposed over the dielectric layer and adjacent the second conductive feature, wherein the third conductive feature comprises a second top and a second bottom, wherein the first top of the second conductive feature is located at a first level between the second top and the second bottom of the third conductive feature, and the second bottom of the third conductive feature is located at a second level between the first top and the first bottom of the second conductive feature.

12. The interconnect structure of claim 11, further comprising an etch stop layer disposed on the second and third conductive features.

13. The interconnect structure of claim 11, wherein a distance between the first level and the second level ranges from about 25 percent of a height of the second conductive feature and about 95 percent of the height.

14. The interconnect structure of claim 11, wherein the second conductive feature further comprises a first sidewall, the third conductive feature further comprises a second sidewall, and a distance between the first sidewall and the second sidewall ranges from about 0.5 times to about 1.5 times a width of the third conductive feature.

15. The interconnect structure of claim 11, further comprising a fifth conductive feature disposed over the dielectric layer and a sixth conductive feature disposed over the dielectric layer.

16. The interconnect structure of claim 15, further comprising:
a protect layer in contact with the fifth conductive feature and the sixth conductive feature;
a dielectric spacer disposed on the protect layer; and
a dielectric fill material disposed on the dielectric spacer, wherein the protect layer, the dielectric spacer, and the dielectric fill material are disposed between the fifth conductive feature and the sixth conductive feature.

17. An interconnect structure disposed over a substrate, comprising:
a first dielectric layer;
a first conductive line disposed in the first dielectric layer;
a second dielectric layer disposed over the first dielectric layer and the first conductive line;
a conductive via disposed in the second dielectric layer;
a second conductive line disposed over the conductive via, wherein the second conductive line comprises a first top and a first bottom;
an etch stop layer disposed on the second conductive line; and
a conductive feature extending from the etch stop layer to the first dielectric layer, wherein the conductive feature comprises a conductive line portion and a conductive via portion, and the conductive line portion comprises a second bottom located at a level between the first top and the first bottom of the second conductive line.

18. The interconnect structure of claim 17, wherein the second conductive line further comprises a first sidewall, and the conductive line portion further comprises a second sidewall, wherein a distance between the first sidewall and the second sidewall ranges from about 0.5 times to about 1.5 times a width of the conductive line portion.

19. The interconnect structure of claim 18, wherein a first angle is defined by the first sidewall and the first bottom, a second angle is defined by the second sidewall and the second bottom, and the first angle is substantially different from the second angle.

20. The interconnect structure of claim 19, wherein the first and second angles are supplementary.
